(19) United States
(12) Patent Application Publication
(10) Pub. No.: US 2005/0095515 A1
(43) Pub. Date: May 5, 2005

(54) Methods and systems for processing overlay data

(75) Inventor: Joseph C. Pellegrini, Cohasset, MA (US)

Correspondence Address: FOLEY HOAG, LLP;PATENT GROUP, WORLD TRADE CENTER WEST, 155 SEAPORT BLVD, BOSTON, MA, 02110, US

(73) Assignee: Inficon Lt, Inc., Cambridge, MA (US)

(21) Appl. No.: 10/928,053

(22) Filed: Aug. 27, 2004

Related U.S. Application Data
(60) Provisional application No. 60/499,262, filed on Aug. 29, 2003.

(51) Int. Cl. G03F 9/00; G03C 5/00; G01B 11/00

(52) U.S. Cl. 430/30; 430/22; 356/399

(57) ABSTRACT

Disclosed are methods, systems, and processor program products for filtering overlay measurements, including generating a residual between a measured overlay displacement and an overlay displacement based on a model of reticle errors relative to an exposure field, grouping the residuals based on location, normalizing residuals within a group based on at least one normalization factor, and, filtering the overlay measurements by comparing the normalized residuals to a threshold.

### CLAIM OF PRIORITY

This application claims priority to U.S. Ser. No. 60/499,262 filed on 29 Aug. 2003, the contents of which are herein incorporated by reference in their entirety.

### BACKGROUND

(1) Field

The disclosed methods and systems relate generally to control techniques, and more particularly to control systems for materials manufacturing processes such as semiconductor manufacturing processes.

(2) Description of Relevant Art

Lithography is a process used in semiconductor manufacturing to transfer a circuit pattern from a photomask or reticle to a semiconductor wafer, or more specifically, to transfer the photomask pattern to a layer of resist that has been deposited on the wafer surface, where the resist is sensitive to irradiation. Different types of lithography can be based on the wavelength of the radiation used to expose the resist. For example, photolithography, otherwise known as optical lithography, uses ultraviolet (UV) radiation and a corresponding UV-sensitive resist. Ion beam lithography uses a resist sensitive to an ion beam, electron beam lithography uses a resist film sensitive to a scanning beam of electrons to deposit energy therein, and X-ray lithography uses a resist sensitive to X-rays.

Photolithography employs a photomask that can be understood to be a quartz plate that is transparent to UV radiation and includes a master copy of an integrated circuit that is often a microscopic integrated circuit. The photomask can be used to block resist exposure to select areas using chrome opaque areas.

A stepper is a resist exposure tool used in many photolithography systems to expose part of the wafer or resist in a given exposure. Systems employing a stepper can require a “step-and-repeat” process to expose the entire wafer as desired. A scanner is another type of resist exposure tool used in photolithography systems to expose part of the wafer or resist in a given exposure. Systems employing a scanner can require a “step-and-scan” process to expose the entire wafer as desired. In the aforementioned systems, overlay can be understood as the superposition of the pattern on the mask to a reference pattern previously created on the wafer surface. Related to overlay is alignment, which can be understood to be including positioning, or aligning, the mask or reticle relative to markers or targets on the wafer, prior to the exposure. Accordingly, to achieve proper exposure, overlay and alignment, among other parameters, must be properly controlled.

As the demand for smaller and more complex circuits increases, there is similarly increased demand for monitoring and hence improving overlay and alignment errors. Contributing to such errors can be the x-alignment of the wafer, the y-alignment of the wafer, the scale error or ratio of desired to actual stage movement in the x and y directions, the rotational error of the wafer, the reticle magnification error, and the reticle rotation error, among others.

### SUMMARY

Described herein is a signature and/or fingerprint filter for use in identifying erroneous overlay measurements. In some embodiments, the disclosed filter can provide improved false positive and false negative rates to allows for a more accurate rejection of invalid overlay data based upon an increased sensitivity threshold when compared to other methods.

Disclosed herein are thus methods, systems, and processor program products disposed on a processor readable medium, for filtering overlay measurements. The disclosed methods and systems include generating a residual between a measured overlay displacement and an overlay displacement based on a model of reticle errors relative to an exposure field, grouping the residuals based on location, normalizing residuals within a group based on a normalization factor(s), and, filtering the overlay measurements by comparing the normalized residuals to a threshold. The model can be based on a target layer and a reference layer, and hence the overlay displacement measurement based on the model can include a modeled displacement between the target layer and the reference layer. The model can be based on at least one exposure tool that imprinted a target and/or a reference layer. The model can also be based on systematic overlay displacement errors associated with at least one exposure tool.

The methods and systems can thus include selecting the model based an exposure tool(s), and/or identifying the model based an exposure tool(s), and/or generating the model based on an exposure tool(s).

In one embodiment, the model can be represented and/or generated by model coefficients that can be generated by sampling the overlay measurements, fitting the sampled overlay measurements to a model, and, computing the model coefficients for the sampled locations. Fitting the sampled data can include using a least squares regression technique and/or a Gauss-Jordan matrix manipulation.

For the disclosed methods and systems, generating a residual can include establishing a coordinate system include four degrees of freedom, where two of said four degrees of freedom define a grid coordinate of a wafer location in an exposure field, the wafer location corresponding to a Cartesian right-hand-rule coordinate of a center of the exposure field relative to the wafer's geometric center, and where two of said four degrees of freedom define an intrafield coordinate of the wafer location in the exposure field corresponding to a Cartesian right-hand-rule coordinate of the wafer location relative to the exposure field center. Accordingly, in one embodiment, grouping the residuals based on location includes grouping the residuals based on intrafield location, where the intrafield location includes a coordinate of a wafer location in an exposure field which corresponds to a Cartesian right-hand-rule coordinate of the wafer location relative to the exposure field center.

In some embodiments, normalizing the residuals within a group includes determining a normalization factor(s), which can include determining a normalization factor for each group. The normalization factor can include a mean of the residuals in the group, a median of the residuals in the group, and/or a constant.

For the disclosed methods and systems, filtering of the overlay measurements can include filtering in two dimensions. For example, filtering the overlay measurements can include comparing a first dimension of the normalized residuals to a first threshold, comparing a second dimension of the normalized residuals to a second threshold, and filtering the overlay measurements based on at least one of the comparings. The filtering can include identifying an overlay measurement as invalid and/or eliminating an overlay measurement from being used for feedback control.

Other objects and advantages will become apparent hereinafter in view of the specification and drawings.

### BRIEF DESCRIPTION OF THE DRAWINGS

FIG. 1 illustrates a control system using feedback;

FIGS. 2A and 2B illustrates further detail for a data processing/analysis system that can be used in a system such as, for example, a system according to FIG. 1;

FIG. 3 illustrates one embodiment of a disclosed fingerprint filter;

FIG. 4 illustrates another embodiment of a disclosed fingerprint filter; and,

FIG. 5 illustrates another control system.

### DESCRIPTION

To provide an overall understanding, certain illustrative embodiments will now be described; however, it will be understood by one of ordinary skill in the art that the systems and methods described herein can be adapted and modified to provide systems and methods for other suitable applications and that other additions and modifications can be made without departing from the scope of the systems and methods described herein.

Unless otherwise specified, the illustrated embodiments can be understood as providing exemplary features of varying detail of certain embodiments, and therefore, unless otherwise specified, features, components, modules, and/or aspects of the illustrations can be otherwise combined, separated, interchanged, and/or rearranged without departing from the disclosed systems or methods. Additionally, the shapes and sizes of components are also exemplary and unless otherwise specified, can be altered without affecting the scope of the disclosed and exemplary systems or methods of the present disclosure.

For the disclosed methods and systems, references to a reticle can include a mask and a photomask, and variations thereof. Further, references to a database can be understood to be a memory that can be capable of associating memory elements.

References herein to a controlling a reticle-induced error(s) in a process system can be understood to include controlling errors in a process system that may physically employ or otherwise include a reticle, and/or process systems that may be affected by reticle characteristics (e.g., errors), regardless of whether a reticle is employed or actually physically included in the process system. The disclosed process systems can thus be understood to be associated with at least one reticle, where the such reticle(s) can be further associated with at least one reticle error. Accordingly, references herein to “the process system reticle,” etc., can be understood to be the one or more reticles whose errors can affect the process system, regardless of whether the reticle(s) may be physically present in the process system.

Described herein is a signature and/or fingerprint filter for use in identifying erroneous overlay measurements. In some embodiments, the disclosed filter can provide improved false positive and false negative rates to allows for a more accurate rejection of invalid overlay data based upon an increased sensitivity threshold when compared to other methods and systems. For example, while prior art systems may use an approximate 50 nm threshold, the disclosed methods and systems may employ a threshold of substantially approximately 5 nm in some embodiments. This increased sensitivity threshold can increase the number and type of invalid measurements that can be detected and accurately and/or properly rejected, thereby preserving the integrity of measurements.

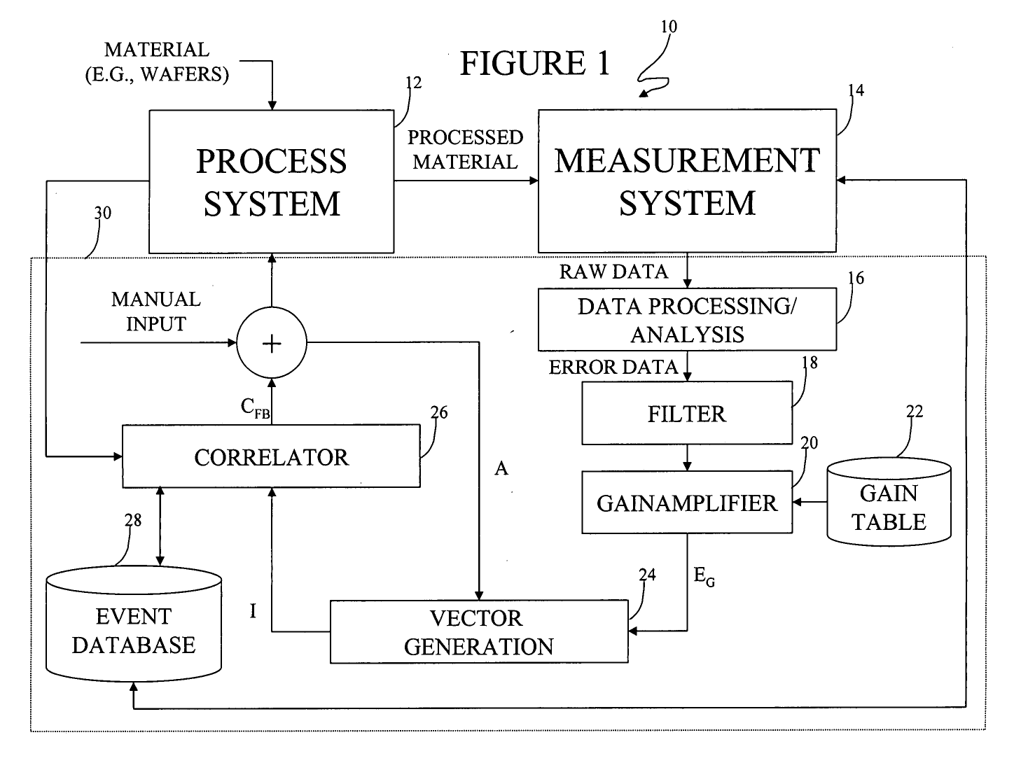

FIG. 1 provides one illustrative depiction of a system 10 that includes a process system that can be associated with semiconductor manufacturing. In accordance with FIG. 1, materials such as semiconductor wafers can be input to a process system 12 and hence to a measurement system 14. The illustrated process system 12 can be, for example, a system that performs lithography, chemical mechanical polish (CMP), diffusion, thin film, metal deposition, ion implantation, etching, or another process system. The illustrated measurement system 14 can be, for example, a metrology system such as an overlay measurement system or tool, a critical dimension measurement tool, a thickness measurement tool, a film reflectivity measurement tool, or another measurement tool or system. Accordingly, for one such embodiment based on FIG. 1, semiconductor wafers can be presented to a photolithography system 12 and thereafter to an overlay measurement tool 14 that provides measurements based on the processed wafers.

As shown in FIG. 1, raw data from the measurement system 14 can be provided for processing and/or analysis 16, where the raw data can include measurements from the measurement system 14, configuration data (e.g., component identifiers, system identifiers, etc.) based on the process system 12 and/or the measurement system 14, and other data (e.g., date, time, etc.). For a system according to FIG. 1, a data processing/analysis module 16 can be based on the process system 12 such that the output of the data processing/analysis module 16 can be configured to provide data in a form that can be used by and/or is otherwise compatible with the process system 12. In some systems, for example, the data processing/analysis module 16 can include modules for modeling and/or otherwise estimating at least some components and/or processes of the process system 12. In an illustrative embodiment where the process system 12 can be a lithography system and the measurement system 14 can be an overlay measurement system, the data processing/analysis module 16 can include, for example, least square regression models for components of the lithography system 12. Those with ordinary skill in the art will recognize that such models and/or estimation modules are not limited to least square regression models, and other estimation and/or modeling techniques can be used without departing from the scope of the disclosed methods and systems.

In the illustrated embodiments, the data processing/analysis module 16 can provide error signals and/or data as output. Accordingly, in an embodiment based on the aforementioned lithography system, the data processing/analysis module 16 can provide error data that can include errors based on, for example, x-translation, y-translation, x-scaling, y-scaling, wafer rotation, grid non-orthogonality, reticle magnification, reticle rotation, and/or others, where those of ordinary skill in the art will recognize that such error signals are merely for illustration and not limitation, and some embodiments may include fewer and/or more error data, where the error data can be in either analog and/or digital form. Unless otherwise provided herein, the data throughout the disclosed embodiments and the disclosed methods and systems can be understood to be in either digital or analog form without departing from the scope of the disclosed methods and systems.

Although the data processing/analysis module 16 is not limited to providing error data as output, for the discussion herein, such module's output can be referred to collectively as error data, where such error data can also include data based on the configuration of the process system 12 and/or the measurement system 14, and/or other data. To facilitate an understanding of systems and methods according to FIG. 1, the error data can be understood to include an error vector that can have at least one row and at least one column, where the size of the error vector can be based on the process system 12 and/or the measurement system 14.

Systems and methods according to FIG. 1 can also include a filter 18 that can operate on data based on the data processing/analysis output, and filter such data based on fixed and/or variable criteria. A system administrator, user, or another can establish or otherwise provide the filter criteria. In one illustrative system, the filter 18 can be based on user-defined rules that can qualify the filter input data to determine whether such filter input data should be employed for controlling and/or otherwise characterizing the process system 12. The filter 18 may be viewed as providing a condition for utilizing the input data to characterize the process system 12. For example, the filter 18 can distinguish data based on a number of successfully measured raw data points provided by the measurement system 14, where the number can be user-specified in some embodiments. In one embodiment, if a specified number of successfully measured raw data points are not provided, the data can be distinguished as inappropriate for feedback to the process system 12 in accordance with a system based on FIG. 1. Additionally and/or optionally, the filter 18 can route or otherwise distinguish or classify data based on data markers, flags, or other data that can indicate that the data input to the filter 18 can be ignored or may otherwise be inappropriate for feedback to the process system 12. In one example, the error data can be marked or otherwise designated as being associated with a special event. In some embodiments, the filter 18 can include validation rules that can be applied to the data input to the filter 18. In illustrative systems, the filter 18 can include statistical and/or other filtering techniques that can include, for example, classification techniques such as Bayesian classifiers and neural networks.

Systems and methods according to FIG. 1 can also include a gain amplifier 20 that can be a variable gain amplifier. A gain table 22 can accordingly provide stored gain values that adjust data based on the filtered error vector to compensate for scaling, sign differences, and other process system 12 and/or measurement system 14 characteristics. A gain amplifier output, Eg, can be provided to a vector generation module 24 that can provide a difference between: (a) data representing actual control data (offsets, commands, etc.), A, provided to the process system 12; and, (b) the gain amplifier output, Eg. The difference vector I=A−Eg, can be understood to represent an actual control to the process system 12, less the errors generated by such control. Those of ordinary skill in the art will recognize that the delay in providing the actual control, A, and receiving the error vectors, Eg, can be on the order of seconds, minutes, hours, or days.

Data based on the difference vector I can be provided to a correlator module 26 that identifies and processes data from events having similar process system 12 characteristics. For example, for a given process system 12, events having similar characteristics can include events that are processed using similar configurations of the process system 12 and/or measurement system 14. In an embodiment where the process system 12 can be a lithography system and the measurement system 14 can be an overlay measurement system, for example, characteristics can include a lithography system identifier, a reticle identifier, a routing identifier (e.g., material used in processing), an operation identifier (e.g., operation being performed), a process level identifier (e.g., stage of processing), an exposure tool identifier, and/or a part number, although such examples are provided for illustration and not limitation, and fewer and/or more system characteristics can be used to characterize an event. An event database 28 or other memory component can thus include historical measurement data that can be provided by the measurement process 14 and thereafter be accessed by or otherwise integrated with the correlator module 26 to allow a feedback control and/or command vector, C_{FB}, to be computed based on a historical evaluation of similar process system 12 and/or measurement system 14 configurations. In some embodiments, C_{FB} can provide incremental control/commands to the process system 12, while in some embodiments, C_{FB} can provide an absolute control/command to the process system 12. Those of ordinary skill in the art will recognize that in the illustrated embodiment, the dimension of C_{FB} can be based on or be the same as Eg, as the commands provided by C_{FB} can be associated with the process system components for which error data can be obtained.

In some embodiments, event database data can be associated and/or correlated to facilitate queries of the event database 28. In the illustrated system, the event database 28 can associate actual command data, A, and gain amplifier outputs, Eg, with “correlation keys” that represent process system characteristics, and can otherwise be understood to be query and/or index terms. Accordingly, as shown in FIG. 1, the correlator module 26 can provide a command vector, C_{FB}, to the process system 12, where C_{FB} can be based on a query of the event database 28 and associated I vector data that can be based on the query. The event database query can otherwise be understood to be a “feedback request,” and as provided herein, can be based on correlation keys or process system characteristics.

One of ordinary skill will recognize that although not explicitly indicated in the illustrated embodiments, the event database 28 can include actual command data A, and gain amplifier outputs Eg that may otherwise be understood as errors. Accordingly, an ideal vector, or difference vector, I, can be recreated from respective A and Eg data.

In one embodiment, the command vector, C_{FB}, can be based on a weighted moving average of historical difference vectors (e.g., “I vectors”) that can be further based on similar process system characteristics and included in the event database 28. The weighted moving average can also be based on a user-specified time-period that can specify a time over which the I vector data can be collected for incorporation into, for example, a weighted moving average. The weighted moving average can be based on fixed and/or variable weights that can be specified by a user, for example. As provided previously herein, in some embodiments, the command vector can be of the same dimension as the gain amplifier output, Eg, and can include similar vector elements. For example, in accordance with a process system 12 that includes a lithography system or tool, a command vector may include at least one control associated with at least one of an x-translation error, a y-translation error, an x-scaling error, a y-scaling error, a wafer rotation error, a non-orthogonality error, an asymmetric magnification error, an asymmetry rotation error, a reticle rotation error, a reticle magnification error, a critical dimension (CD) linewidth bias, a dose bias, a reticle density, a mask density, a frame-to-frame alignment, a distance from optical center to frame center, an alignment mark line size, an alignment mark density, and an alignment mark duty cycle, although such examples are provided for illustration and not limitation.

The illustrated event database 28 can employ a commercially available database (e.g, SQL, Informix, Oracle, Access, etc.) or another system for associating data and allowing such associated data to be queried and/or retrieved according to the methods and systems disclosed herein. In an embodiment where the process system 12 includes a lithography system, the event database 28 can be arranged to associate data based on, for example, process system characteristics and/or other correlation keys that can include a technology identifier (e.g., type of processor, operating system, etc.), a reticle identifier, a route identifier, an operation identifier, a process level identifier, an exposure tool identifier, and/or a part number, although such examples are merely illustrative, and some embodiments can use fewer and/or more identifiers or process system characteristics.

The correlator module 26 can thus also include or otherwise provide for rules for querying the event database 28. In an embodiment, a user and/or system administrator can provide default query rules that can be modified using, for example, an interface such as a graphical user interface (GUI). For example, a user may provide the correlator module 26 with a hierarchy of query criteria and filter criteria such that one or more correlation keys or query criteria can be eliminated from the query or otherwise presented as a wildcard in the query if the filtered query results are not sufficient. Accordingly, query results can be filtered based on default and/or user-specified criteria that can include, for example, a minimum number of query results, a maximum number of query results, a time period within which the data may have been collected, and/or a type of weighting average to apply. In an embodiment, if the filtered query results are inadequate to allow for a computation of the control/command vector, C_{FB}, the disclosed methods and systems can allow for a wildcarding of system parameters based on a user's hierarchical wildcarding configuration. Such a system can thus perform several feedback requests or database queries and filterings before obtaining query results sufficient for computing C_{FB}.

In one example, a user may query the event database 28 based on process system characteristics that include a technology identifier (ID), a routing identifier (ID), a process level identifier (ID), an operation identifier (ID), a device (or part number) identifier (ID), a reticle identifier (ID), an exposure tool identifier (ID), and/or another process system characteristic. The query may further specify or it may otherwise be known that data satisfying such process system characteristics must be within a time period in the last M weeks, and further, at least N data points must be collected for a valid retrieval. Because the criteria for N data points within the past M weeks may not be satisfied in an initial query, the user may decide to wildcard, for example, the exposure tool ID criteria to potentially allow further data points (i.e., satisfying the query regarding process system characteristics other than exposure tool ID). If N data points with M weeks are not retrieved after querying without employing exposure tool ID, the user may specify that the next process system criteria to be eliminated from the query may be reticle ID. Those of ordinary skill in the art will recognize this example as providing an illustration of the aforementioned hierarchical wildcarding, where query terms and/or correlation keys can be specified as employing an exact match (e.g., Windows 2000 operating system), a partial wildcard (e.g., a Windows operating system), or a complete wildcard (e.g., operating system not relevant). As provided herein, the user can additionally and optionally establish a hierarchical rule for invoking the wildcards (e.g., in the example herein, exposure tool ID was ranked as the first parameter to wildcard, followed by reticle ID, etc.).

In some cases, the wildcarding process may not provide sufficient query results for allowing a computation of C_{FB}. In an embodiment, a user or another can be alerted or otherwise informed when C_{FB} cannot be computed because of insufficient query results, and such condition may require a manual adjustment to a system according to FIG. 1.

As illustrated in FIG. 1, some embodiments can allow a user or another to provide a manual input (e.g., user-specified input) to override or otherwise compensate the command vector, C_{FB}. Accordingly, a system based on the illustrated control system 30 can include one or more processor-controlled devices that can interface to the process system 12 and the measurement system 14, where a user, system administrator, or another, referred to throughout herein collectively as a user, can access data at various stages of the control system 30 via a user interface (e.g., GUI, operating system prompt) and utilize one or more peripheral devices (e.g., memory, keyboard, stylus, speaker/voice, touchpad, etc.) to provide input or otherwise alter data at various stages of the control system 30. A user can also utilize tools that can be incorporated into or otherwise interface with the control system 30 to analyze or otherwise view data at various stages of the control system 30, where such analysis can be performed in real-time and/or off-line. Accordingly, changes to the components of such a control system 30 can be performed in real-time and/or off-line.

Those of ordinary skill in the art will recognize that in an example where the FIG. 1 process system 12 can be a lithographic system and the measurement system 14 can be an overlay measurement tool, the lithographic system 12 can be configured by a user to query for data from the correlator module 26 and/or event database 28 to provide an initial command vector, C_{FB}, where such query can also include or otherwise be based on process system characteristics, hierarchical rules, wildcarding, and/or other criteria. Based on the filtered query results, a C_{FB} can be provided for an initial wafer. If a C_{FB} cannot be computed based on a lack of filtered query results, systems and methods according to FIG. 1 may cause a “send-ahead” wafer to allow processing and measurements upon which control can be provided. Using send-ahead wafers and other such techniques can be costly and can adversely affect the throughput of the methods and systems. As provided herein, to reduce the occurrences of ineffective queries and hence “send-ahead” wafers, users may devise a query that wildcards enough process system characteristics to obtain a desired number of query results to provide an initial C_{FB}, but such wildcarding techniques can cause incompatible data (e.g., based on different process system characteristics from that presently occurring in the process system 12) to be included in the C_{FB} computation, and hence be ineffective in providing the desired control. For example, a user can wildcard reticle ID, thus allowing the query to combine (e.g., compute a weighted moving average) based on different reticle IDs. In this example, because different reticles have different reticle errors, such errors remain uncompensated, and hence can combine in undesirable manners to induce undesirable system performance, particularly when the process system 12 is presently utilizing or otherwise affected by a specific reticle.

Those of ordinary skill will understand that the exemplary methods and systems of FIG. 1 are merely illustrative of one general embodiment, and can include variations thereof, including but not limited to embodiments provided by co-pending U.S. Ser. No. 10/229,575, filed 28 Aug. 2002, and entitled “Methods and Systems for Controlling Reticle-Induced Errors,” assigned to the same Assignee as the present disclosure, and incorporated herein by reference in its entirety.

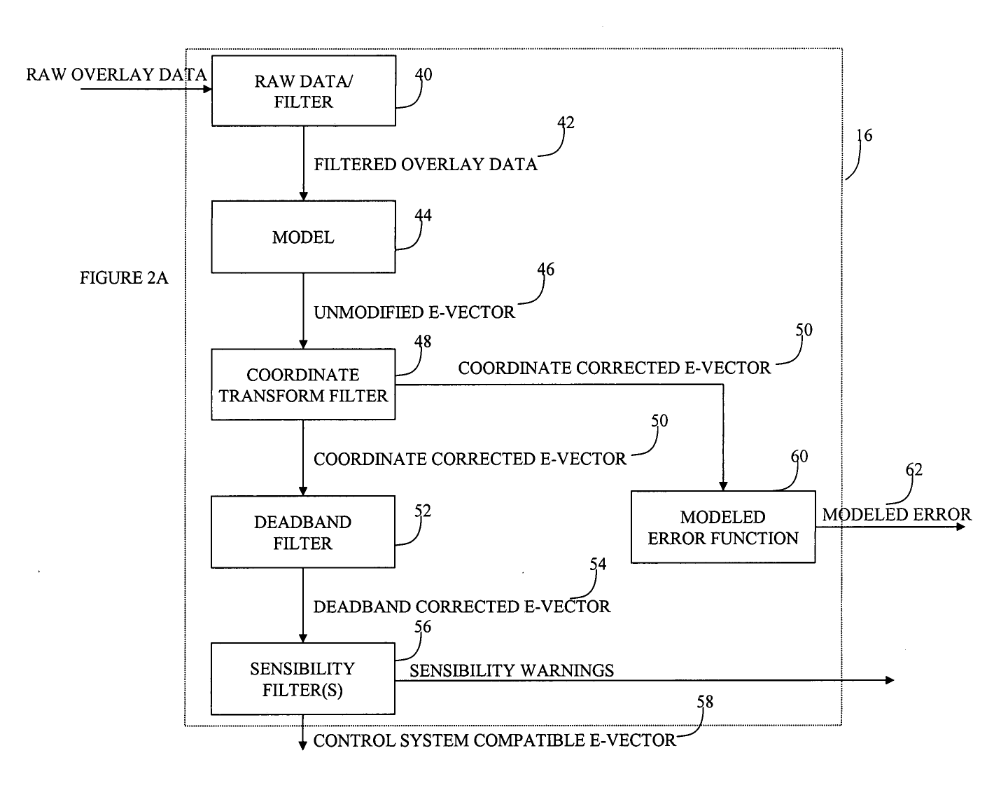

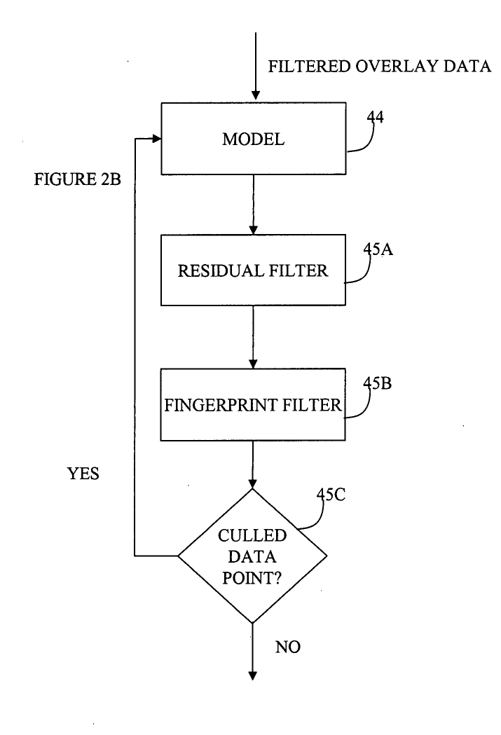

Referring again to FIG. 1, the data processing analysis 16 can be further described as provided by FIG. 2A. As FIG. 2A provides, for a system according to FIG. 1 where the measurement system 14 is and/or includes an overlay measurement tool, overlay data can be provided to a filter 40, described further herein, that can provide as output filtered overlay data 42 to a model 44 that can be based on the process system 12 and can thus provide for a comparison between the filtered data 42 and data based on the model 44. The comparison of the filtered data 42 to the model 44 can allow for an unmodified error vector 46 that can be provided to a coordinate transfer filter 48 to provide a coordinate corrected error vector 50 (e.g., convert the “raw” wafer origin and orientation coordinate data from a metrology tool into a coordinate system referenced by an exposure tool). The coordinate corrected error vector can optionally be input to a deadband filter 52 to provide a deadband corrected error vector 54, and/or optionally thereafter to one or more sensibility filters 56 to generate an error vector compatible with the embodiment 58 and the associated control system thereof. As FIG. 2A also indicates, the coordinated corrected error vector 50 can additionally and/or optionally be provided to a modeled error function 60 that can generate a modeled error 62.

With reference to FIG. 2B, as provided with respect to FIG. 2A, a raw data filter 42 (e.g., an absolute filter) can accept the raw data prior to modeling 44. Additionally and/or optionally, after modeling 44, the disclosed methods and systems can include a residual filter 45A, and a fingerprint filter 45B. In such embodiments, if either the residual or the fingerprint filter culls a data point 45C, the modeling 44 can be repeated.

As provided in FIG. 2B, the filter 45B can be associated with certain filter limits. In some embodiments and under certain circumstances, the overlay errors, referred to herein as Δxᵢ and Δyᵢ, may exceed the filter limits, and thus cause erroneous and/or invalid data throughout the methods and systems such as those of FIGS. 1 and 2, which could cause problems such as, for example, high false negative and/or positive rejection rates, etc.

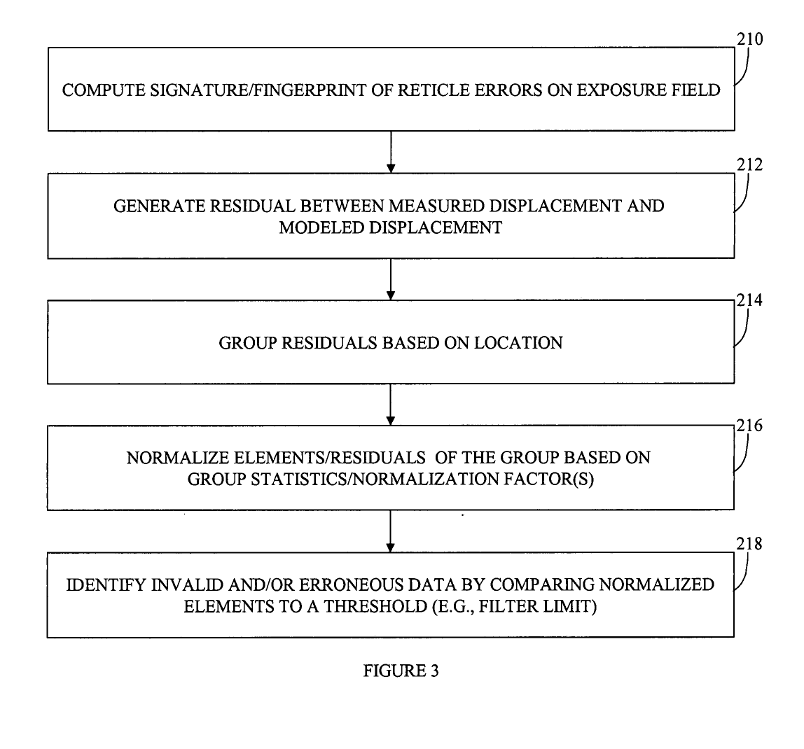

The disclosed methods and systems can employ as the filter 45B what may be referred to herein as a “signature” and/or “fingerprint” filter that can employ aspects of an “absolute filter,” and/or aspects of a “residual filter” (or “sigma filter”) as such are known in the art. FIG. 3 shows one example of one method and system to develop the disclosed fingerprint filter.

As provided in FIG. 3, the disclosed methods and systems are predicated on a concept that reticle errors may be likely to form a repeating signature and/or fingerprint on each exposure field. Accordingly, the disclosed methods and systems allow for a computing, determination, and/or selection of model of a signature and/or fingerprint of such reticle errors on a given exposure field(s) 210. The methods and systems thus allow for a generation of a residual 212 between a measured displacement at a given location, and the corresponding location in the model. Thereafter, residuals at the same relative location in the exposure field (and/or within a tolerance of the same location) can be grouped 214 and normalized 216. For example, the normalizing 216 can include generating a mean, median, and/or other statistic and/or normalization factor based on the group, and adjusting/normalizing the elements of the group accordingly using the normalization factor. In some embodiments, the normalization factor can be a constant value, and thus, although the illustrated methods and systems contemplate a normalization factor for each group, some embodiments may employ a normalization factor across one or more groups. Normalized residuals can thus be compared to a threshold value 218 to identify erroneous data.

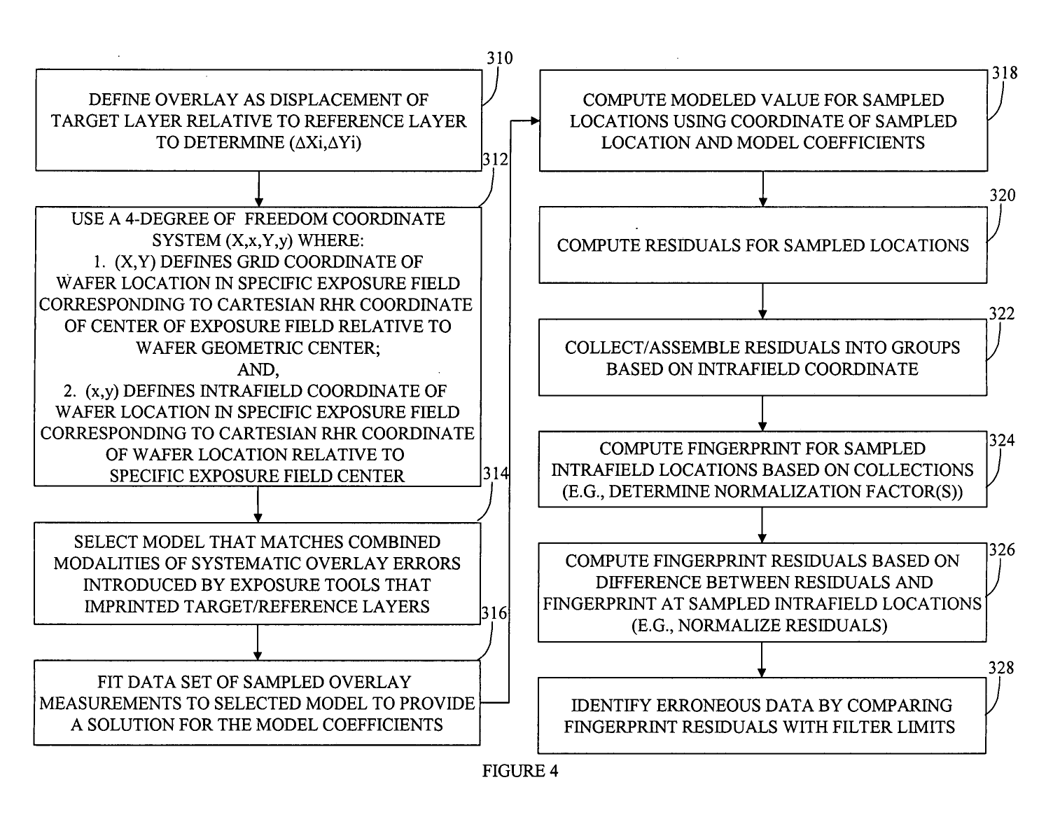

FIG. 4 provides an example of the disclosed methods and systems in further detail. In the embodiment shown in FIG. 4, a measurement system (e.g., FIG. 1, 14) can be understood to provide measurements upon which a data processing/analysis module (e.g., FIG. 1, 16) can generate overlay error data that can be provided to a filter (e.g., FIG. 1, 16 and/or FIG. 2, 40), where overlay can be defined and/or understood to include one or more measures of a displacement of a target layer (e.g., upper layer) relative to a reference layer (e.g., lower layer) in the x and y directions, with such displacement being expressed herein as a coordinate pair of (Δxᵢ, Δyᵢ) 310. For the disclosed fingerprint filter, a coordinate system of a substrate can be defined based on microelectronic manufacturing, where such coordinate system includes four degrees of freedom 312. Such coordinate system can be expressed herein as (X, x, Y, y), further based upon a repeat step-and-scan coordinate system. Accordingly, (X, Y) can represent a “grid coordinate” of a wafer location associated with a specific exposure field, and where the (X, Y) coordinate is a Cartesian right-hand rule coordinate of the center of an exposure field relative to the wafer's geometric center. Further, the (x, y) coordinate can represent the “intrafield coordinate” of a wafer location belonging to a specific exposure field, where the (x, y) coordinate is a Cartesian right-hand rule coordinate with respect to a location of interest relative to the center of the specific exposure field.

A model can be selected, generated, and/or defined 314 to match and/or otherwise be compatible with and/or be associated with the combined modalities of the systematic overlay errors introduced by types of exposure tools imprinted by the target and reference layers. The model is thus based on the exposure tools used to imprint the target and/or reference layers. Those of ordinary skill understand, for example, that various tools are available for developing and/or defining such a model.

The data set composed of the sampled overlay measurements, (Δxᵢ, Δyᵢ), can be fit to the selected model 316 using a general accepted technique including, for example, least-squares regression using Gauss-Jordan matrix manipulation, with such example provided for illustration and not limitation. Such fitting can cause a solution for the coefficients of the model such that the sum of the squares of the residual can be minimized relative to other solutions. Accordingly, for different sampled locations, a modeled value can be computed 318 using the coordinate of the sampled location and the coefficients of the model. Thereafter, a residual for sampled locations can be computed 320, where one embodiment uses the following residual computation:
Residual Δxᵢ=|Measured Δxᵢ−Modeled Δxᵢ|
Residual Δyᵢ=|Measured Δyᵢ−Modeled Δyᵢ|

Although in some systems, erroneous data can be identified by a discriminating function, as follows: if (|Residual Δxᵢ|>filter limit X) or (|Residual Δyᵢ|>filter limit Y), then measurement i is marked “invalid;” however, for the disclosed filter, the aforementioned residual values can be grouped and/or otherwise associated 322 such that members of a group have similar intrafield (x, y) coordinates. In one embodiment, members of a group have the same intrafield (x, y) coordinates, while in other embodiments, members of a group may have the same intrafield (x, y) coordinates within a certain tolerance that can be determined manually and/or automatically.

A fingerprint value can thus be computed for sampled intrafield locations 324 based on the groupings, for example, by computing the median values of Residual Δxᵢ and Residual Δyᵢ within a group:
Fingerprint Δxi=Median (Residual Δx amongst members of a group); and
Fingerprint Δyi=Median (Residual Δy amongst members of a group).

A fingerprint residual may thus be computed 326 as follows:
Fingerprint Residual Δxi=Residual Δxi−Fingerprint Δxi; and,
Fingerprint Residual Δyi=Residual Δyi−Fingerprint Δyi.

For the disclosed methods and systems, erroneous data can thus be identified 328 by the following discriminating function and/or computation:
If (|Fingerprint Residual Δxi|>filter limit X) or (|Fingerprint Residual Δyi|>filter limit Y),
then measurement i is marked “invalid.”

By employing the disclosed systems and methods, erroneous overlay measurements can be identified and/or processed based on such identification (e.g., discarded, provided reduced weighting, etc.). The disclosed methods and systems can enable a scaling of the overlay data filtering method to more advanced processes where critical dimensions and overlay tolerances are more stringent than prior art processes. For example, the approximate 50 nanometer cutoff for the sensitivity of a prior art filter, such as a residual filter, would generally disqualify that method for a process where the minimum critical dimension is 0.15 micrometers or less. In some embodiments, the disclosed Fingerprint Filter method and systems could apply to an approximate 15 nanometer critical dimension manufacturing node based upon a ten-fold improvement in sensitivity.

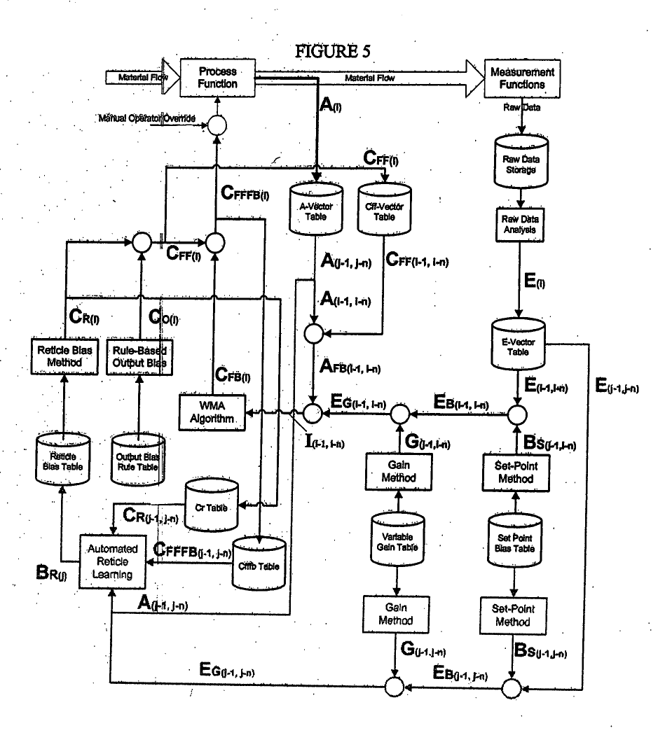

FIG. 5 shows another example of a closed loop controller that can employ the disclosed fingerprint filter. The system of FIG. 5 is otherwise described in pending U.S. application Ser. No. 10/723,640, filed on Nov. 26, 2003.

What has thus been described are methods, systems, and processor program products for filtering overlay measurements, including generating a residual between a measured overlay displacement and an overlay displacement based on a model of reticle errors relative to an exposure field, grouping the residuals based on location, normalizing residuals within a group based on at least one normalization factor, and, filtering the overlay measurements by comparing the normalized residuals to a threshold.

The methods and systems described herein are not limited to a particular hardware or software configuration, and may find applicability in many computing or processing environments. The methods and systems can be implemented in hardware or software, or a combination of hardware and software. The methods and systems can be implemented in one or more computer programs, where a computer program can be understood to include one or more processor executable instructions. The computer program(s) can execute on one or more programmable processors, and can be stored on one or more storage medium readable by the processor (including volatile and non-volatile memory and/or storage elements), one or more input devices, and/or one or more output devices. The processor thus can access one or more input devices to obtain input data, and can access one or more output devices to communicate output data. The input and/or output devices can include one or more of the following: Random Access Memory (RAM), Redundant Array of Independent Disks (RAID), floppy drive, CD, DVD, magnetic disk, internal hard drive, external hard drive, memory stick, or other storage device capable of being accessed by a processor as provided herein, where such aforementioned examples are not exhaustive, and are for illustration and not limitation.

The computer program(s) can be implemented using one or more high level procedural or object-oriented programming languages to communicate with a computer system; however, the program(s) can be implemented in assembly or machine language, if desired. The language can be compiled or interpreted.

As provided herein, the processor(s) can thus be embedded in one or more devices that can be operated independently or together in a networked environment, where the network can include, for example, a Local Area Network (LAN), wide area network (WAN), and/or can include an intranet and/or the internet and/or another network. The network(s) can be wired or wireless or a combination thereof and can use one or more communications protocols to facilitate communications between the different processors. The processors can be configured for distributed processing and can utilize, in some embodiments, a client-server model as needed. Accordingly, the methods and systems can utilize multiple processors and/or processor devices, and the processor instructions can be divided amongst such single or multiple processor/devices.

The device(s) or computer systems that integrate with the processor(s) can include, for example, a personal computer(s), workstation (e.g., Sun, HP), personal digital assistant (PDA), handheld device such as cellular telephone, laptop, handheld, or another device capable of being integrated with a processor(s) that can operate as provided herein. Accordingly, the devices provided herein are not exhaustive and are provided for illustration and not limitation.

References to “a microprocessor” and “a processor”, or “the microprocessor” and “the processor,” can be understood to include one or more microprocessors that can communicate in a stand-alone and/or a distributed environment(s), and can thus can be configured to communicate via wired or wireless communications with other processors, where such one or more processor can be configured to operate on one or more processor-controlled devices that can be similar or different devices. Use of such “microprocessor” or “processor” terminology can thus also be understood to include a central processing unit, an arithmetic logic unit, an application-specific integrated circuit (IC), and/or a task engine, with such examples provided for illustration and not limitation.

Furthermore, references to memory, unless otherwise specified, can include one or more processor-readable and accessible memory elements and/or components that can be internal to the processor-controlled device, external to the processor-controlled device, and/or can be accessed via a wired or wireless network using a variety of communications protocols, and unless otherwise specified, can be arranged to include a combination of external and internal memory devices, where such memory can be contiguous and/or partitioned based on the application. Accordingly, references to a database can be understood to include one or more memory associations, where such references can include commercially available database products (e.g., SQL, Informix, Oracle) and also proprietary databases, and may also include other structures for associating memory such as links, queues, graphs, trees, with such structures provided for illustration and not limitation.

References to a network, unless provided otherwise, can include one or more intranets and/or the internet. References herein to microprocessor instructions or microprocessor-executable instructions, in accordance with the above, can be understood to include programmable hardware.

Unless otherwise stated, use of the word “substantially” can be construed to include a precise relationship, condition, arrangement, orientation, and/or other characteristic, and deviations thereof as understood by one of ordinary skill in the art, to the extent that such deviations do not materially affect the disclosed methods and systems.

Throughout the entirety of the present disclosure, use of the articles “a” or “an” to modify a noun can be understood to be used for convenience and to include one, or more than one of the modified noun, unless otherwise specifically stated.

Elements, components, modules, and/or parts thereof that are described and/or otherwise portrayed through the figures to communicate with, be associated with, and/or be based on, something else, can be understood to so communicate, be associated with, and or be based on in a direct and/or indirect manner, unless otherwise stipulated herein.

Many additional changes in the details, materials, and arrangement of parts, herein described and illustrated, can be made by those skilled in the art. Accordingly, it will be understood that the following claims are not to be limited to the embodiments disclosed herein, can include practices otherwise than specifically described, and are to be interpreted as broadly as allowed under the law.

1. A method for filtering overlay measurements, the method comprising:
generating a residual between a measured overlay displacement and an overlay displacement based on a model of reticle errors relative to an exposure field,
grouping the residuals based on location,
normalizing residuals within a group based on at least one normalization factor, and,
filtering the overlay measurements by comparing the normalized residuals to a threshold.

2. A method according to claim 1, where the model is based on a target layer and a reference layer, and the overlay displacement measurement based on the model includes a modeled displacement between the target layer and the reference layer.

3. A method according to claim 1, where the model is based on at least one exposure tool that imprinted at least one of a target and a reference layer.

4. A method according to claim 1, where the model is based on systematic overlay displacement errors associated with at least one exposure tool.

5. A method according to claim 1, where generating a residual includes:
establishing a coordinate system include four degrees of freedom, where two of said four degrees of freedom define a grid coordinate of a wafer location in an exposure field, the wafer location corresponding to a Cartesian right-hand-rule coordinate of a center of the exposure field relative to the wafer's geometric center, and where two of said four degrees of freedom define an intrafield coordinate of the wafer location in the exposure field corresponding to a Cartesian right-hand-rule coordinate of the wafer location relative to the exposure field center.

6. A method according to claim 1, where grouping the residuals based on location includes grouping the residuals based on intrafield location, where the intrafield location includes a coordinate of a wafer location in an exposure field which corresponds to a Cartesian right-hand-rule coordinate of the wafer location relative to the exposure field center.

7. A method according to claim 1, where normalizing the residuals within a group includes determining a normalization factor.

8. A method according to claim 1, where normalizing the residuals within a group includes determining a normalization factor for each group.

9. A method according to claim 1, where the normalization factor includes at least one of: a mean of the residuals in the group, a median of the residuals in the group, and a constant.

10. A method according to claim 1, where filtering the overlay measurements includes filtering in two dimensions.

11. A method according to claim 1, where filtering the overlay measurements includes:
comparing a first dimension of the normalized residuals to a first threshold,
comparing a second dimension of the normalized residuals to a second threshold, and
filtering the overlay measurements based on at least one of the comparings.

12. A method according to claim 1, where filtering the overlay measurements includes identifying an overlay measurement as invalid.

13. A method according to claim 1, where filtering the overlay measurements includes eliminating an overlay measurement from being used for feedback control.

14. A method according to claim 1, further comprising at least one of:
selecting the model based at least one exposure tool, and,
identifying the model based on at least one exposure tool.

15. A method according to claim 1, further comprising generating the model based on at least one exposure tool.

16. A method according to claim 15, where generating the model includes determining model coefficients by:
sampling the overlay measurements,
fitting the sampled overlay measurements to the model, and,
computing model values for the sampled locations.

17. A method according to claim 16, where fitting the sampled data includes using a least squares regression technique.

18. A method according to claim 16, where fitting the sampled data includes using a Gauss-Jordan matrix manipulation.

19. A processor program product disposed on at least one processor-readable medium, the processor program product including processor instructions for causing at least one processor to:
generate a residual between a measured overlay displacement and an overlay displacement based on a model, where the model is a model of reticle errors relative to an exposure field,
group the residuals based on location,
normalize residuals within a group based on at least one normalization factor, and,
filter the overlay measurements by comparing the normalized residuals to a threshold.

20. A processor program product according to claim 19, where the model is based on a target layer and a reference layer, and the overlay displacement measurement based on the model includes a modeled displacement between the target layer and the reference layer.

21. A processor program product according to claim 19, where the model is based on at least one exposure tool that imprinted at least one of a target and a reference layer.

22. A processor program product according to claim 19, where the model is based on systematic overlay displacement errors associated with at least one exposure tool.

23. A processor program product according to claim 19, where the instructions to generate a residual include instructions to:
establish a coordinate system include four degrees of freedom, where two of said four degrees of freedom define a grid coordinate of a wafer location in an exposure field, the wafer location corresponding to a Cartesian right-hand-rule coordinate of a center of the exposure field relative to the wafer's geometric center, and where two of said four degrees of freedom define an intrafield coordinate of the wafer location in the exposure field corresponding to a Cartesian right-hand-rule coordinate of the wafer location relative to the exposure field center.

24. A processor program product according to claim 19, where the instructions to group the residuals based on location include instructions to group the residuals based on intrafield location, where the intrafield location includes a coordinate of a wafer location in an exposure field which corresponds to a Cartesian right-hand-rule coordinate of the wafer location relative to the exposure field center.

25. A processor program product according to claim 19, where the instructions to normalize the residuals within a group include instructions determine a normalization factor.

26. A processor program product according to claim 19, where the instructions to normalize the residuals within a group include instructions to determine a normalization factor for each group.

27. A processor program product according to claim 19, where the normalization factor includes at least one of: a mean of the residuals in the group, a median of the residuals in the group, and a constant.

28. A processor program product according to claim 19, where the instructions to filter the overlay measurements include instructions to filter in two dimensions.

29. A processor program product according to claim 19, where the instructions to filter the overlay measurements include instructions to:
compare a first dimension of the normalized residuals to a first threshold,
compare a second dimension of the normalized residuals to a second threshold, and
filter the overlay measurements based on at least one of the comparings.

30. A processor program product according to claim 19, where the instructions to filter the overlay measurements include instructions to identify an overlay measurement as invalid.

31. A processor program product according to claim 19, where the instructions to filter the overlay measurements include instructions to eliminate an overlay measurement from being used for feedback control.

32. A processor program product according to claim 19, further comprising instructions to perform at least one of:
select the model based at least one exposure tool, and,
identify the model based on at least one exposure tool.

33. A processor program product according to claim 19, further comprising instructions to generate the model based on at least one exposure tool.

34. A processor program product according to claim 33, where the instructions to generate the model include instructions to determine model coefficients by:
sampling the overlay measurements,
fitting the sampled overlay measurements to a model, and,
computing model values for the sampled locations.

35. A processor program product according to claim 34, where the instructions to fit the sampled data include instructions to use a least squares regression technique.

36. A processor program product according to claim 34, where the instructions to fit the sampled data include instructions to use a Gauss-Jordan matrix manipulation.
